(19) United States
(12) Patent Application Publication
(10) Pub. No.: US 2026/0182269 A1
(43) Pub. Date: Jun. 25, 2026

(54) GAPFILL FOR DEVICE INTEGRATION

(71) Applicant: Applied Materials, Inc., Santa Clara, CA (US)

(72) Inventors: Jongbeom SEO, Santa Clara, CA (US); Raghuveer Satya MAKALA, Santa Clara, CA (US); Tomohiko KITAJIMA, San Jose, CA (US); Abhijit Basu MALLICK, Fremont, CA (US); Praket Prakash JHA, San Jose, CA (US); Mandar B. PANDIT, Milpitas, CA (US); Shweta HARDIKAR, Santa Clara, CA (US); Hoi Sung CHUNG, Sunnyvale, CA (US); Chang Seok KANG, San Jose, CA (US)

(21) Appl. No.: 18/999,762

(22) Filed: Dec. 23, 2024

(51) Int. Cl. H01L 21/02; C23C 16/02; C23C 16/455; H10B 12/00

(52) U.S. Cl. CPC H10P 14/6529; C23C 16/02; C23C 16/45525; H10P 14/6339; H10P 14/69215; H10P 14/6922; H10B 12/01

(57) ABSTRACT

A method for dielectric gapfill includes forming a liner layer on inner surfaces of a lateral opening, filling the opening with a flowable dielectric layer on the liner layer by exposing the flowable dielectric layer to a steam, and densifying the flowable dielectric layer, forming a dielectric layer within the opening.

### BACKGROUND

### Field

Embodiments described herein generally relate to semiconductor device fabrication, and more particularly, to methods of forming a high quality thin oxide layer in a high aspect ratio semiconductor structure.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, lateral channel structures used in 3D dynamic random access memory (DRAM) devices and vertical channel structures used in 4F² DRAM devices may have an aspect ratio of 6:1, 10:1, 20:1, or more and require dielectric fill without seams or voids.

A typical gapfill process, by atomic layer deposition (ALD) or chemical vapor deposition (CVD), to fill such structures, may provide conformal deposition. However, there are certain structures where open critical dimension (CD) differences are intentionally designed, and conformal deposition may not be suited for these types of structures. In such cases, the conformal deposition can result in the formation of seams or voids over a wide area, even with unwanted film deposition, which can lead to complications during downstream processing.

Thus, there is a need for improved processes for gapfill preventing formation of seems or voids in lateral channel structures.

### SUMMARY

Embodiments of the present disclosure provide a method for dielectric gapfill. The method includes forming a liner layer on inner surfaces of a lateral opening, filling the opening with a flowable dielectric layer on the liner layer, and densifying the flowable dielectric layer by exposing the flowable dielectric layer to a steam, forming a dielectric layer within the lateral opening.

Embodiments of the present disclosure also provide a method for dielectric gapfill. The method includes forming a liner layer on inner surfaces of an opening, partially etching the liner layer within the opening, filling the opening with a flowable dielectric layer on the liner layer, and densifying the flowable dielectric layer, forming a dielectric layer within the opening.

Embodiments of the present disclosure further provide a method for dielectric gapfill. The method includes filling an opening with a flowable dielectric layer on exposed inner surfaces of the opening, and densifying the flowable dielectric layer, forming a dielectric layer within the opening.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a substrate processing system according to one embodiment.

FIG. 2 is a process flow diagram of a method of forming an oxide layer in a semiconductor structure according to one embodiment.

FIGS. 3A, 3B, 3B′, 3B″, 3C, 3C′, 3C″, 3D, 3D′, and 3D″ are schematic views of a semiconductor structure according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein are directed to methods of dielectric gapfill in a semiconductor device, such as lateral channel structures used in 3D dynamic random access memory (DRAM) devices and vertical channel structures used in 4F² DRAM devices.

The methods described herein include forming a liner on inner surfaces of a narrow lateral opening and filling the opening with dielectric material by a flowable deposition. This combination allows filling the narrow lateral opening without forming seams or voids, providing a more optimal solution for gap fill applications.

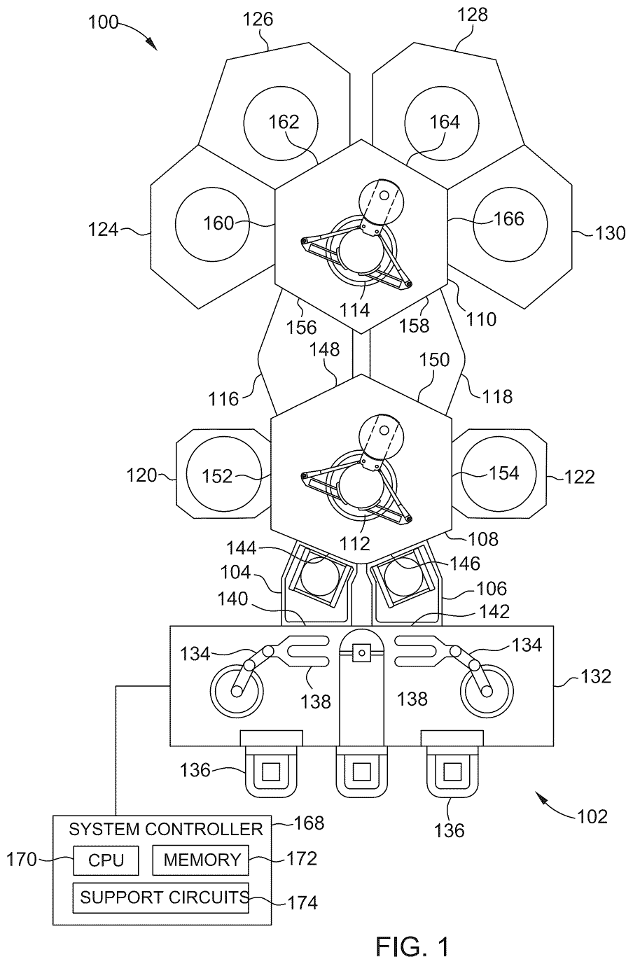

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

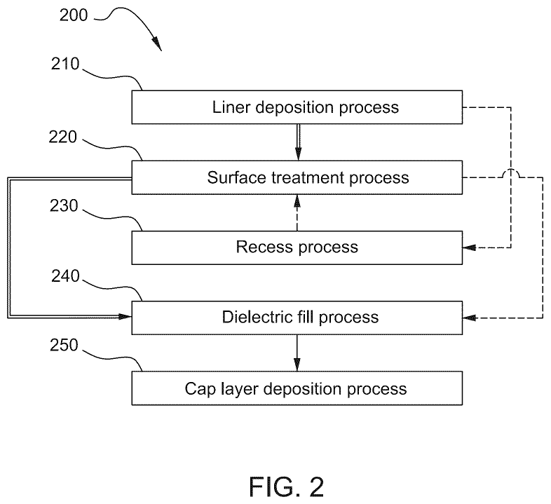

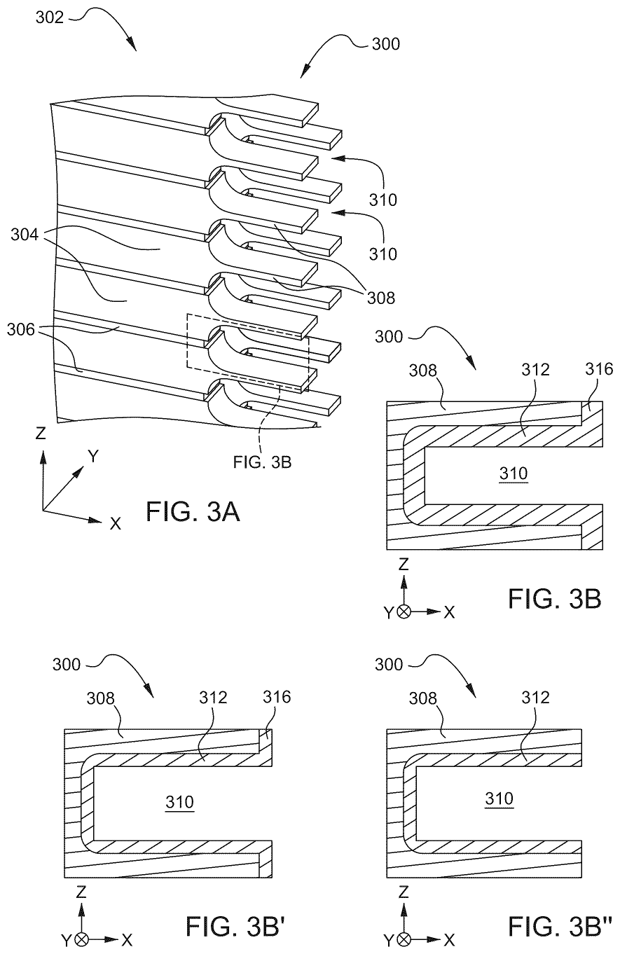

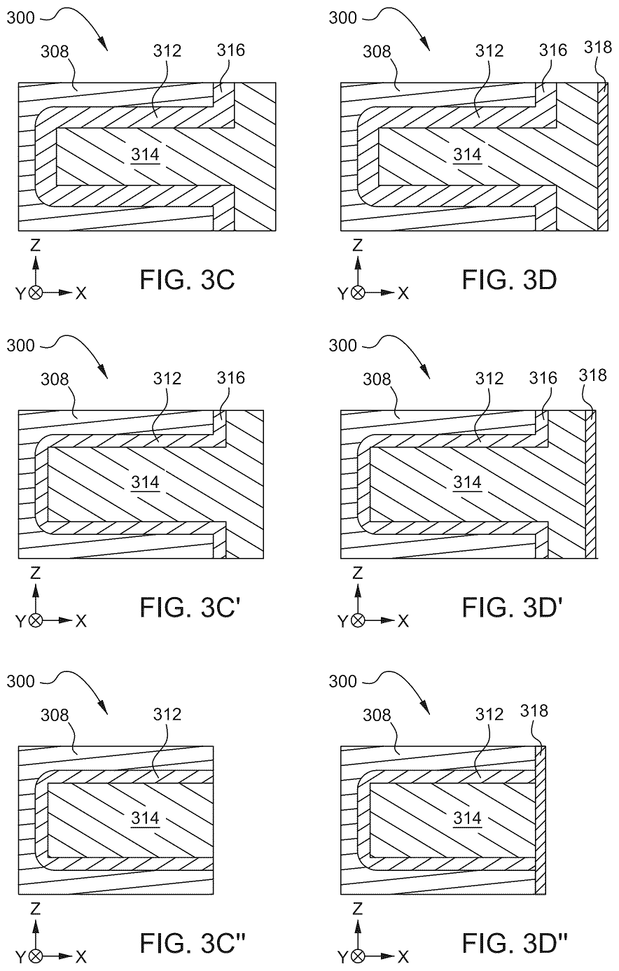

FIG. 2 is a process flow diagram of a method 200 of dielectric gapfill in a semiconductor structure 300 that may form a portion of lateral channels in a 3D dynamic random access memory (DRAM) device, according to one or more implementations of the present disclosure. FIG. 3A is an isometric view of the semiconductor structure 300 and FIGS. 3B, 3B′, 3B″, 3C, 3C′, 3C″, 3D, 3D′, and 3D″ are enlarged cross-sectional views of the semiconductor structure 300 corresponding to various stages of the method 200. Additionally, the method 200 may be used to form buried wordline (bWL) structures in 4F² DRAM cell transistor structure or other semiconductor devices, such as nanowires, that require seam/void free dielectric gapfill in a high aspect ratio structure. Further, it should also be understood that the operations depicted in FIG. 2 may be performed simultaneously and/or in a different order than the order depicted in FIG. 2.

The semiconductor structure 300 includes fin-shaped columns 302 (one shown) formed on a substrate (not shown). The fin-shaped columns 302 each extend in the X direction and are isolated from adjacent fin-shaped columns 302 in the Y direction by a front inter-layer dielectric (ILD) (not shown). The fin-shaped columns 302 each include a stack of alternating channel layers 304 and sacrificial layers 306 in the Z direction and have a width in the Y direction of between about 30 nm and about 150 nm. The fin-shaped columns 302 may be formed by epitaxially growing the stack of alternating channel layers 304 and sacrificial layers 306 on the substrate, and patterning the stack of alternating channel layers 304 and sacrificial layers 306.

The channel layers 304 may be formed of silicon (Si), each having a thickness of between about 3 nm and about 13 nm, for example, about 8 nm. The sacrificial layers 306 may be formed of silicon germanium (SiGe) with a ratio of germanium (Ge) ranging between about 10 % and about 25 %. The sacrificial layers 306 may each have a thickness of between about 3 nm and about 15 nm, for example, about 10 nm.

As shown in FIG. 3A, portions 308 of the channel layers 304 are thinned and lateral openings 310 are formed between the adjacent thinned channel layer portions 308. This thinning of the channel layers 304 may be performed by any wet etch process, performed in a processing chamber, such as the processing chamber 120 shown in FIG. 1. The thinned channel layer portions 308 may have a thickness in the Z direction of about 3 nm and about 13 nm, a depth in the X direction of between about 50 nm and about 200 nm, and spacing between the adjacent thinned channel layer portions 308 in the Z direction of between about 40 nm and about 90 nm.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100>, Si <110>, or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins with a liner deposition process in block 210, in which a liner layer 312 is formed conformally on exposed surfaces of the thinned channel layer portions 308 (e.g., exposed inner surfaces of the lateral opening 310 and remaining exposed surfaces of the thinned channel layer portions 308 outside of the lateral opening 310), as shown in FIG. 3B.

The liner layer 312 may be formed of silicon oxide (SiO₂), silicon nitride (Si₃N₄), silicon oxycarbide (SiCO), silicon carbon nitride (SiCN), silicon carbon oxynitride (SiCON), silicon boron nitride (SiBN), aluminum oxide (Al₂O₃), zirconium oxide (ZrO₂), hafnium oxide (HfO₂), titanium oxide (TiO₂), niobium (Nb₂O₃), titanium nitride (TiN), tungsten (W), molybdenum (Mo), or ruthenium (Ru), having a thickness of between about 10 Å and about 300 Å.

The liner deposition process may include any appropriate deposition process, such as atomic layer deposition (ALD), or chemical vapor deposition (CVD), performed in a processing chamber, such as the processing chamber 126, 128, or 130 shown in FIG. 1.

The liner layer 312 may prepare surfaces on which flowable material can be deposited in the subsequent dielectric fill process. In some embodiments in which the lateral opening 310 has a low aspect-ratio (e.g. between about 100 Å and about 700 Å) or the exposed inner surfaces of the lateral opening 310 is formed of silicon oxide (SiO₂), a liner layer 312 may not be needed and the liner deposition process in block 210 may be omitted.

In some embodiments, in block 220, a surface treatment process is performed to modify surfaces (e.g., exposed surfaces of the liner layer 312, exposed inner surfaces of the opening 310) on which flowable material can be deposited in the subsequent dielectric fill process.

The surface treatment process may include a thermal anneal process in reducing environment that includes oxygen(O₂), ozone(O₃), nitrous oxide (N₂O), carbon oxide (CO), nitrogen (N₂), hydrocarbons (CₓH_{y}) (e.g., methane (CH₄), ethane (C₂H₆), propane (C₃H₈), butane (C₄H₁₀), pentane (C₅H₁₂), hexane (C₆H₁₄)), hydrogen (H₂), ammonia (NH₃), a mixture thereof, and inert gas (e.g., helium (He), argon (Ar)) and other noble gas, performed in a rapid thermal processing (RTP) chamber, such as the processing chamber 120, 122, 124, 126, 128, or 130 shown in FIG. 1. The thermal anneal process may be performed for between about 10 second and about 3600 seconds, at a temperature of between about 300° C. and about 650° C., and at a pressure of between about 1 Torr and 760 Torr.

The surface treatment may include a plasma treatment process in a continuous mode or a pulsed mode, performed in a pre-clean chamber, such as the processing chamber 122 shown in FIG. 1. In the plasma treatment process, exposed surfaces of the semiconductor structure 300 are exposed to a plasma formed from a process gas including oxygen(O₂), ozone(O₃), nitrous oxide (N₂O), hydrogen (H₂), nitrogen (N₂), a mixture of hydrogen (H₂) and nitrogen (N₂), a mixture of hydrogen (H₂) and methane (CH₄), a mixture of hydrogen (H₂) and noble gas (e.g., helium (He), argon (Ar)), carbon oxide (CO), ammonia (NH₃), or any combination thereof. The plasma treatment process may be a radical-based pre-cleaning technique using a remote plasma assisted process in a continuous mode or a pulsed mode. The plasma treatment process may be a capacitively coupled plasma (CCP) process or inductively coupled plasma process (ICP). The plasma treatment process may be performed at a temperature of between about 300° C. and about 650° C. for a duration of between about 10 seconds and about 3600 seconds.

The surface treatment may include a radical treatment process, performed in a radical treatment chamber, such as the processing chamber 122 shown in FIG. 1. The radical treatment process includes exposing the semiconductor structure 300 to a radical species, such as oxygen, NH radicals, at a treatment temperature of less than about 1000° C., such about 900° C., at a treatment pressure of between about 0.1 Torr and about 10 Torr, such as about 1 Torr, for a treatment time of between about 1 minute and about 60 minutes, such as about 2 minutes. The radicals are supplied to the processing region of the radical treatment chamber at a flow rate of between about 1,300 sccm and about 2,200 sccm, such as about 1,350 sccm or 2,100 sccm, for a 300 mm diameter substrate. The radicals can be generated using one or more of a remote plasma source (RPS), an inductively coupled plasma (ICP) source, and/or one or more microwave resonators for in-situ generation.

In some embodiments, in block 230, a recess process is performed to partially etch the formed liner layer 312 and widen the lateral opening 310, as shown in FIG. 3B′ and 3B″. In FIG. 3B″, a portion 316 of the liner layer 312 is removed and the thinned channel layer portions 308 are partially exposed. The surface treatment process in block 220 may be performed after the recess process in block 230 is performed, as indicated by dashed arrows in FIG. 2.

The recess process may include any isotropic etch process, such as wet etching, thermal etching, or radical etching, or any anisotropic etch process, such as plasma etching, or reactive ion etching (RIE), performed in a processing chamber, such as the processing chamber 120 shown in FIG. 1.

In block 240, a dielectric fill process is performed to fill the lateral opening 310 with a dielectric layer 314, as shown in FIGS. 3C, 3C′, and 3C″. The dielectric layer 314 is formed on the liner layer 312. FIG. 3C depicts the semiconductor structure 300 in which the recess process in block 230 is not performed. FIG. 3C′ depicts the semiconductor structure 300 in which the recess process in block 230 is performed as shown in FIG. 3B′. FIG. 3C″ depicts the semiconductor structure 300 in which the recess process in block 230 is performed as shown in FIG. 3B″.

The dielectric layer 314 may be formed of silicon oxide (SiO₂), silicon oxycarbide (SiCO), or silicon carbon oxynitride (SiCON).

The dielectric fill process may include a flowable CVD process, performed in a processing chamber, such as a Producer® Eterna® FCVD™ or the processing chamber 126, 128, or 130 shown in FIG. 1. In the dielectric fill process, dielectric precursor is delivered into the lateral opening 310, forming a flowable dielectric layer, by a flowable CVD process, and subsequently densified to form the dielectric layer 314 in a solid phase. The densification may include exposing the flowed material to a steam in a high pressure environment.

In block 250, a cap layer deposition process is performed to form a cap layer 318 on exposed surfaces of the semiconductor structure 300, as shown in FIGS. 3D, 3D′, and 3D″. FIG. 3D depicts the semiconductor structure 300 in which the recess process in block 230 is not performed. FIG. 3D′ depicts the semiconductor structure 300 in which the recess process in block 230 is performed as shown in FIG. 3B′. FIG. 3D″ depicts the semiconductor structure 300 in which the recess process in block 230 is performed as shown in FIG. 3B″. The cap layer 318 seals exposed surfaces of the dielectric layer 314 and the thinned channel layer portions 308 (in FIG. 3D″).

The cap layer 318 may be formed of silicon oxide (SiO₂) having a thickness of between about 10 Å and about 500 Å. The cap layer deposition process may include atomic layer deposition (ALD), performed in a processing chamber, such as the processing chamber 126, 128, or 130 shown in FIG. 1.

In the ALD process, the semiconductor structure 300 is exposed to a silicon-containing precursor, such as silane (SiH₄), disilane (Si₂H₆), tetrasilane (Si₄H₁₀), or a combination thereof.

It should be noted that the methods described herein can be applied to forming a gate oxide layer in vertical trench openings in 4F² DRAM devices, and a thin nanowire field-effect-transistor (FET) such as gate-all-around field-effect transistor (GAA FET) devices.

In the embodiments described herein methods of dielectric gapfill in a semiconductor device, such as lateral channel structures used in 3D dynamic random access memory (DRAM) devices and vertical channel structures used in 4F² DRAM devices, are provided.

The methods described herein include forming a liner on inner surfaces of a narrow lateral opening and filling the opening with dielectric material by a flowable deposition. This combination allows filling the narrow lateral opening without forming seams or voids, providing a more optimal solution for gap fill applications.

While the foregoing is directed to embodiments of the present disclosure, other and further embodiments of the disclosure may be devised without departing from the basic scope thereof, and the scope thereof is determined by the claims that follow.

1. A method for dielectric gapfill, comprising:
forming a liner layer on inner surfaces of a lateral opening;
filling the opening with a flowable dielectric layer on the liner layer; and
densifying the flowable dielectric layer by exposing the flowable dielectric layer to a steam, forming a dielectric layer within the lateral opening.

2. The method of claim 1, wherein the liner layer comprises silicon oxide (SiO₂), silicon nitride (Si₃N₄), silicon oxycarbide (SiCO), silicon carbon nitride (SiCN), silicon carbon oxynitride (SiCON), silicon boron nitride (SiBN), aluminum oxide (Al₂O₃), zirconium oxide (ZrO₂), hafnium oxide (HfO₂), titanium oxide (TiO₂), niobium (Nb₂O₃), titanium nitride (TiN), tungsten (W), molybdenum (Mo), or ruthenium (Ru).

3. The method of claim 1, wherein the dielectric layer comprises silicon oxide (SiO₂), silicon oxycarbide (SiCO), or silicon carbon oxynitride (SiCON).

4. The method of claim 1, wherein forming the liner layer comprises atomic layer deposition (ALD), or chemical vapor deposition (CVD).

5. The method of claim 1, wherein filling the lateral opening with the flowable dielectric layer comprises a flowable chemical vapor deposition (CVD) process.

6. The method of claim 1, further comprising:
prior to filling the lateral opening with the flowable dielectric layer, performing a surface treatment process to modify surfaces of the liner layer.

7. The method of claim 1, further comprising:
subsequent to forming the dielectric layer within the lateral opening, forming a cap layer on exposed surface of the dielectric layer.

8. A method for dielectric gapfill, comprising:
forming a liner layer on inner surfaces of an opening;
partially etching the liner layer within the opening;
filling the opening with a flowable dielectric layer on the liner layer; and
densifying the flowable dielectric layer, forming a dielectric layer within the opening.

9. The method of claim 8, wherein the liner layer comprises silicon oxide (SiO₂), silicon nitride (Si₃N₄), silicon oxycarbide (SiCO), silicon carbon nitride (SiCN), silicon carbon oxynitride (SiCON), silicon boron nitride (SiBN), aluminum oxide (Al₂O₃), zirconium oxide (ZrO₂), hafnium oxide (HfO₂), titanium oxide (TiO₂), niobium (Nb₂O₃), titanium nitride (TiN), tungsten (W), molybdenum (Mo), or ruthenium (Ru).

10. The method of claim 8, wherein the dielectric layer comprises silicon oxide (SiO₂), silicon oxycarbide (SiCO), or silicon carbon oxynitride (SiCON).

11. The method of claim 8, wherein forming the liner layer comprises atomic layer deposition (ALD), or chemical vapor deposition (CVD).

12. The method of claim 8, wherein filling the opening with the flowable dielectric layer comprises a flowable chemical vapor deposition (CVD) process.

13. The method of claim 8, further comprising:
prior to filling the opening with the flowable dielectric layer, performing a surface treatment process to modify surfaces of the liner layer.

14. The method of claim 8, further comprising:
subsequent to forming the dielectric layer within the opening, forming a cap layer on exposed surface of the dielectric layer.

15. A method for dielectric gapfill, comprising:
filling an opening with a flowable dielectric layer on exposed inner surfaces of the opening; and
densifying the flowable dielectric layer, forming a dielectric layer within the opening.

16. The method of claim 15, wherein the exposed inner surfaces of the opening comprises silicon oxide (SiO₂).

17. The method of claim 15, wherein the dielectric layer comprises silicon oxide (SiO₂), silicon oxycarbide (SiCO), or silicon carbon oxynitride (SiCON).

18. The method of claim 15, wherein filling the opening with the flowable dielectric layer comprises a flowable chemical vapor deposition (CVD) process.

19. The method of claim 15, further comprising:
prior to filling the opening with the flowable dielectric layer, performing a surface treatment process to modify the exposed inner surfaces of the opening.

20. The method of claim 15, further comprising:
subsequent to forming the dielectric layer within the opening, forming a cap layer on exposed surface of the dielectric layer.
